(19) United States
(12) Patent Application Publication
(10) Pub. No.: US 2004/0029024 A1
(43) Pub. Date: Feb. 12, 2004

(54) Exposure method, mask fabrication method, fabrication method of semiconductor device, and exposure apparatus

(76) Inventor: Hidetoshi Ohnuma, Kanagawa (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/603,689

(22) Filed: Jun. 26, 2003

(30) Foreign Application Priority Data
Jun. 28, 2002 (JP) P2002-189086

(51) Int. Cl. G03F 1/00; G21K 5/00; G03F 7/20; G06F 17/50

(52) U.S. Cl. 430/5; 430/296; 378/34; 430/311; 430/394; 716/19

(57) ABSTRACT

A pair of reflective masks is provided in a photolithography process, wherein pattern forming elements are divided into respective direction relative to a projection vector of an EUV ray, so that each of the reflective masks has the same pattern forming elements extending in one direction. The exposure process is sequentially carried out to an object to be exposed using respective reflective mask, and when the reflection mask is changed from one to the other, the object and the other reflective mask are rotated so that the angle of the object and the projection vector becomes the same angle with the reflective mask before it is changed.

### CROSS REFERENCE TO RELATED APPLICATION

This application claims priority from Japanese Priority Document No. 2002-189086, filed on Jun. 28, 2002 with the Japanese Patent Office, which document is hereby incorporated by reference.

### BACKGROUND OF THE INVENTION

1. Field of the Invention

The present invention relates to an exposure method used in a lithography process for forming a circuit pattern of a semiconductor device, a mask fabrication method of an exposure mask used in this lithography process, a fabrication method of a semiconductor device including this lithography process, and an exposure apparatus.

2. Description of the Related Art

In a lithography process that is one of processes for fabricating a semiconductor device, a wave-length of a light source in an exposure apparatus tends to be shorter along with the miniaturization of forming pattern. For example, the light source has been changed from an i-ray (wave-length=365 nm) to a KrF Excimer (wave-length=248 nm), to an ArF Excimer (wave-length=93 nm), and to an F2 (wave-length=53 nm). This means that in order to principally improve the resolution, it is performed by the increase of a numerical aperture (NA) of a projection optical system and the shortened wave-length of the exposure light. Generally, it is well-known that the resolution determined by the wave-length of an exposure light is expressed by the Rayleigh's formula as w=K1×(λ/NA), wherein w is a resolution of a pattern, NA is a numerical aperture of the projection optical system, and λ is a wave-length of the exposure light. Further, K1 is a positive constant less than 1 determined by the resist and the process used in the exposure process.

Further, it has recently been proposed to use a so-called Extreme Ultra Violet ray (EUV) such as a light of a soft X-ray region having a wave-length of 5 to 15 nm as the exposure light in order to cope with further miniaturization of a pattern. When the EUV ray is employed, the resolution w=43 nm is obtained from the above-mentioned Rayleigh's formula, provided that the K1=0.8, the NA=0.25, and the wave-length of the EUV ray as the exposure light is 13.5 nm. Then, it becomes possible to carry out the process of the pattern that is matching with a design rule for 50 nm pattern width. To that end, the EUV exposure technology is expected to be a future exposure technology as a possible candidate.

In this case, regarding the EUV ray, there is not any material or substance that does not absorb but does transmit the EUV ray, so that it is impossible, for the EUV ray, to configure a light transmission type projection optical system that is widely applied in a conventional lithography process. Accordingly, it is necessary to configure a reflection type projection optical system (including a reflective mask and a reflection type optical system for reflecting a light) in case of using the EUV ray.

FIG. 3 is a schematic diagram designating one example of an exposure apparatus having a reflection type projection optical system. The exposure apparatus in FIG. 3 comprises an optical source 1 for the EUV ray, a reflective mask 2 and a reflection type optical system 3 (plural reflection mirrors, for example), a mask holder 4 for holding the reflective mask 2, a movable reticle stage 5, a wafer holder 6, and a movable wafer stage 7. A wafer 8 as an object to be exposed is to be held on the movable wafer stage 7 by way of the wafer holder 6. As the optical source 1 for the EUV ray, a laser plasma system is pointed out, wherein a high power laser light such as the Excimer laser and the like is focused and irradiated on the EUV ray radiating material such as rare gas spouting from a nozzle (not shown), and generates the EUV ray upon transiting to a low potential condition so that the material is excited to be in plasma state. And the EUV ray irradiated from the light source 1 passes through the reflection type optical system 3, thereby the pattern (the mask pattern) formed on the reflection plane of the reflective mask 2 is projected on the wafer 8 as an LSI pattern (circuit pattern that is necessary for configuration of the semiconductor device). In this case, the illuminated area on the reflective mask 2 is formed in a ring shape, and further, a scanning exposure system is employed, wherein the pattern on the reflective mask 2 is sequentially projected on the wafer 8 by relatively scanning the reflective mask 2 and the wafer 8 relative to the reflection type optical system 3.

FIG. 4 is a perspective view designating an exemplified configuration of the reflective mask 2 used in the exposure apparatus. As shown in this figure, it is known such mask that is equipped with a mask blank 2a for reflecting the EUV ray and an EUV ray absorption film formed so as to cover the reflection plane of the mask blank 2a. The mask blank 2a has a multi-layered film structure formed by alternately stacking a Mo (Molybdenum) film and an Si (Silicon) film, and the repetition number of the stacks is usually 40. By the multi-layered film structure as described above, the mask blank 2a reflects the EUV ray having 13.5 nm in wave-length at reflectivity of approximately 70%. Further, by covering the reflection plane of the mask blank 2a with the absorption film 2b having corresponding pattern thereof, the reflection of the EUV ray is selectively carried out. In this case, if the reflection material such as multi-layered film is carried out the patterning to the absorption film blank, the recovery upon failure is impossible, but if the patterning is carried out by providing such absorption film 2b, it becomes possible to try again and becomes easy to repair the pattern, so that it is preferable to cover the mask blank 2a with the absorption film 2b.

In case of using such reflective mask 2, the light reflected at the reflection plane has to be introduced to the reflection type optical system 3 without mutually interfering with the incident light to the reflection plane. Accordingly, the incident light to the reflective mask 2 has to be a skewed incident light having an incident angle θ relative to a normal line of the reflection plane. The incident angle θ of the incident light is determined by the NA of illumination (hereinafter referred to as an NAill) at the reflection plane, and this is determined by the NA at a wafer surface of a reflective type projection optical system and a magnification of projection based on a desired resolution. For example, provided that the magnification of projection is 4 times system taking over the magnification of projection of a conventional exposure apparatus, the incident angle θ of the incident light to the reflective mask 2 becomes around 4 degrees when the level of the NA=0.2 to 0.3 determined by the desired resolution.

However, in case of the skewed incidence as above described, the pattern width projected on the wafer 8 fluctuates depending on the direction of the mask pattern on the reflective mask 2 relative to the projection vector of the incident light.

In this case, if the mask pattern is for projecting of the LSI pattern, for example, the direction of the mask pattern is divided by whether the mask pattern is parallel or perpendicular relative to the direction of the projection vector of the EUV ray. In other words, the mask pattern for projection of the LSI pattern is normally able to be divided into pattern forming elements having sides parallel to the direction of the projection vector and pattern forming elements having sides orthogonal to the direction of the projection vector. Accordingly, each pattern forming elements comprising the mask pattern is defined as described herein after in this text.

FIG. 5 is a schematic diagram for explaining the direction of the mask pattern. As shown in the figure, the mask pattern formed on the reflective mask 2 is scanned in the Y direction in the figure as the movable reticle stage 5 moves (shown in FIG. 3), and thereby, the mask pattern is projected on the wafer 8. The incident angle θ (4 degrees, for example) of the EUV ray incoming askew at this time is the angle around the X axis in the figure. Accordingly, the pattern forming elements extending in the direction parallel to the scanning direction of the mask pattern, namely the pattern forming elements having sides parallel to the direction of the projection vector are defined as a V-line (Vertical-line). On the contrary, the pattern forming elements extending in the direction vertical to the scanning direction of the mask pattern, namely the pattern forming elements having sides orthogonal the direction of the projection vector are defined as an H-line (Horizontal-line).

FIG. 6 is a schematic diagram for designating one specific example obtained by simulating the difference of the pattern width of the V-line and the H-line after pattern projection when the EUV ray incidents askew. Generally, in case of strictly simulating the difference of the pattern width of the V-line and the H-line, it is necessary to introduce a three-dimensional electromagnetic field simulation on the basis of the thickness of the absorption film 2b (FIG. 4) on the reflective mask 2, but in the figure, it is approached by the case where the EUV ray incidents on a two dimensional binary mask, provided that the thickness of the absorption film 2b is zero. In the result of the simulation depicted in FIG. 6, the projected line width of a line and a space of every V-line and the H-line on the wafer 8 is calculated under the condition where the wave-length of the EUV ray=13.5 nm, the NA=0.25, the σ=0.70, the incident angle on the mask=4 degrees (around X axis), the magnification of projection is 4, and the pattern width of the line and the space on the wafer=50 nm. According to the simulation result, it is recognized that there is the line width difference of around 4 nm between the V-line and the H-line in the range of the focus range of ±0.1 μm. Further, it is recognized that the fluctuation of the V-line and the H-line within the focus range is around 2 times.

As described above, when the EUV ray incidents askew on the reflective mask 2, the width of the line pattern projected on the wafer 8 is fluctuated depending on the direction of the mask pattern relative to the projection vector, and as the result, it is probable to cause an adverse affect to the resolution of the projected image. However, various technologies are conventionally proposed regarding the correction for removing the difference between the width of the projected V-line and H-line patterns, but the technology for improving the margin difference of the resolution depending on the incident angle of the EUV ray upon exposure process which causes fluctuation in the width of the projected V and H line patterns is not particularly proposed. Further, the width of the projected pattern also depends on the repetition rate or the crude density of the pattern on the reflective mask 2 (herein after, this is called as an OPE (Optical Proximity Effect) characteristic), and this OPE characteristic also fluctuates depending on the incident angle of the EUV ray.

### SUMMARY OF THE INVENTION

According to the present invention, it is so arranged not to cause the difference of the pattern width between the V-line and the H-line, namely the influence caused by the direction of the mask pattern relative to the projection vector without depending on the correction of the mask pattern, for example. Namely the present invention is to propose an exposure method capable of improving margin difference of the resolution in the projected image without introducing misalignment or distortion (distortion in pattern width) of the projected image, a mask fabrication method, and a fabrication method of a semiconductor device.

This invention is presented to attain the above-mentioned improvement. Namely, the present invention is an exposure method for projection of a desired pattern on an object to be exposed using a reflective mask for an exposure light, wherein pattern forming elements of a mask pattern corresponding to the above-mentioned desired pattern are divided with regard to respective direction relative to the projection vector of the exposure light and a set of reflective mask patterns each having only the pattern forming elements of the same direction is provided. Then, the projection of the pattern on the object to be exposed is sequentially carried out by the irradiation and the reflection of the exposure light with regard to the reflective mask of respective direction. In this case, when the one reflective mask is change to the other reflective mask, the other reflective mask and the object to be exposed are rotated relative to the projection vector so that the angle of the pattern forming elements of the other reflective mask and the projection vector is becomes equal to the angle of the pattern forming elements of the one reflective mask and the projection vector.

Further the present invention is a mask fabrication method that is presented to attain the above-mentioned improvement. Namely, the present invention is a fabrication method for fabricating a reflective mask to be used for projecting a desired pattern on an object to be exposed by reflecting an exposure light, wherein pattern forming elements of a mask pattern corresponding to the above-mentioned desired pattern are divided with regard to respective direction relative to the projection vector of them, and a set of reflective mask patterns each having only the pattern forming elements of the same direction is provided. With regard to respective reflective mask, each reflective mask and the above-mentioned object to be exposed are rotated relative to the projection vector so that the angle of each of reflective mask and the projection vector is always the same.

Further the present invention is a fabrication method of a semiconductor device that is presented to attain the above-mentioned improvement. Namely, the present invention is a fabrication method of a semiconductor device including a lithography process for projection of a desired pattern on an object to be exposed by using a reflective mask for an exposure light, wherein pattern forming elements of a mask pattern corresponding to the above-mentioned desired pattern are divided with regard to respective direction relative to the projection vector of the exposure light and a set of reflective mask patterns each having only the pattern forming elements of the same direction is provided. Then, the projection of the pattern on the object to be exposed is sequentially carried out by the irradiation and the reflection of the exposure light with regard to the reflective mask of respective direction. In this case, when the one reflective mask is change to the other reflective mask, the other reflective mask and the object to be exposed are rotated relative to the projection vector so that the angle of the pattern forming elements of the other reflective mask and the projection vector is becomes equal to the angle of the pattern forming elements of the one reflective mask and the projection vector.

According to the exposure method, the mask fabrication method, and the fabrication method of a semiconductor device as above-mentioned procedures, the mask patterns corresponding a desired pattern to be formed on an object to be exposed are divided into V-line pattern forming elements and H-line pattern forming elements with regard to respective direction, and a pair of reflective mask patterns each corresponding to respective direction is provided. Then, when the one reflective mask is changed to the other reflective mask, the other reflective mask and the object to be exposed are rotated. Thereby, the angle of the pattern forming elements of the respective mask and the projection vector becomes always the same. Accordingly, even in the case where the exposure light incidents askew on the reflective mask, there is no possibility of causing the difference in the width of the projected pattern depending on the angle between the pattern forming elements and the projection vector.

### BRIEF DESCRIPTION OF THE DRAWINGS

In the accompanying drawings:

FIG. 1 shows a brief overview of an exposure method according to the present invention, wherein (a), (b), and (c) show procedures of the exposure method;

FIG. 2 is a flowchart designating a flow of procedures of a mask fabrication method according to the present invention;

FIG. 3 is a schematic diagram designating one embodiment of an exposure apparatus having a reflection type projection optical system according to the present invention;

FIG. 4 is a perspective view showing one configured example of a reflective mask used in the exposure apparatus in FIG. 3;

FIG. 5 is a schematic diagram for explaining a direction of a mask; and

FIG. 6 is a schematic diagram for designating one specific example obtained by simulating the difference of the pattern width of the V-line and the H-line after projection when the exposure light incidents askew.

### DETAILED DESCRIPTION OF THE PREFERRED EMBODIMENTS

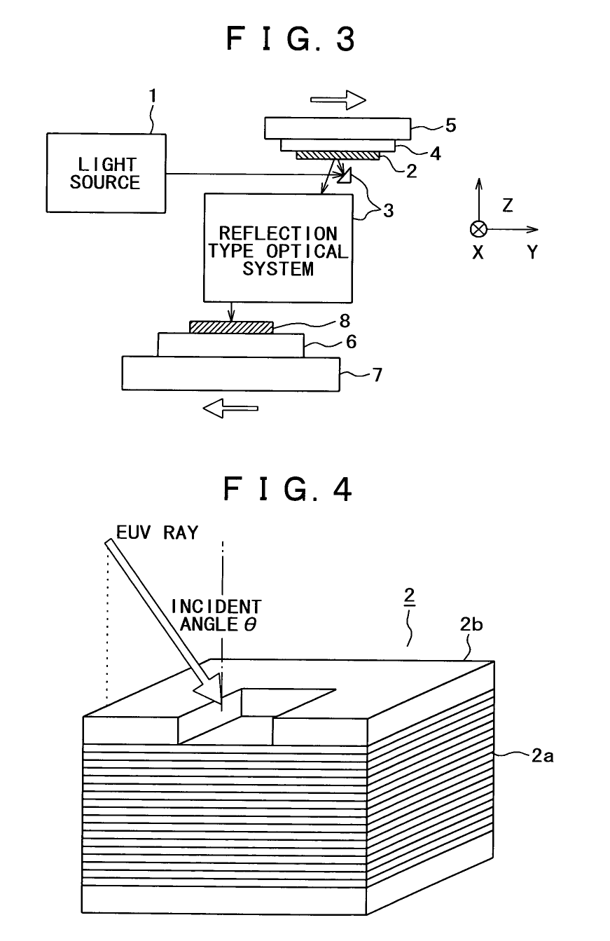

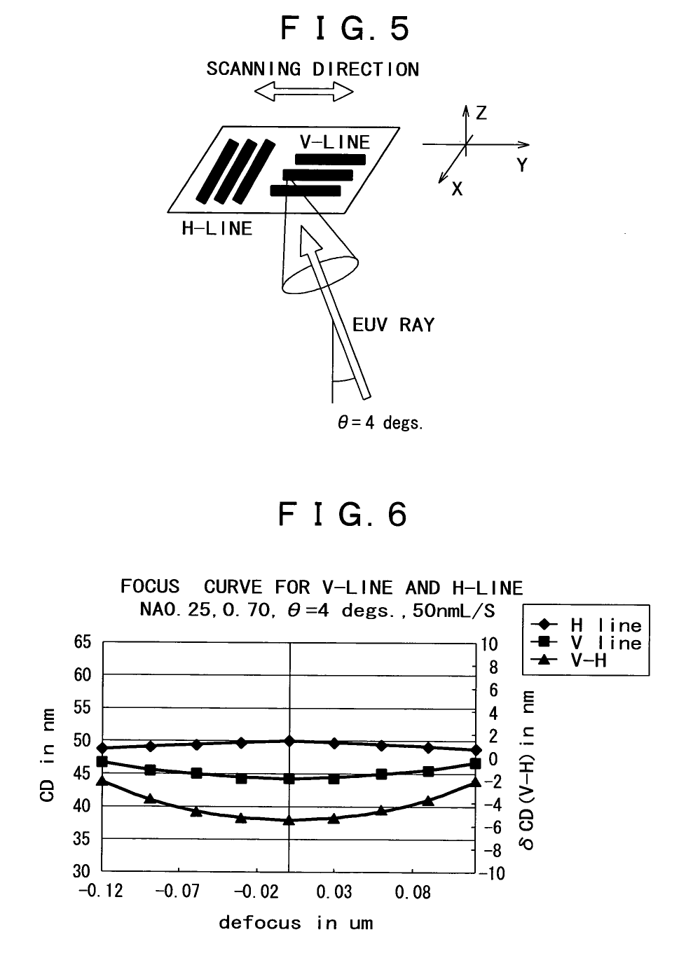

Hereinafter, an exposure method, a mask fabrication method, a fabrication method of a semiconductor device, and an exposure apparatus according to the present invention will be concretely described with reference to the drawings. However, only the difference relative to a conventional one is explained, and explanations for the configuration of an exposure apparatus which is similar to a conventional one (FIG. 3), and the configuration of a reflective mask itself (FIG. 4) are omitted here.

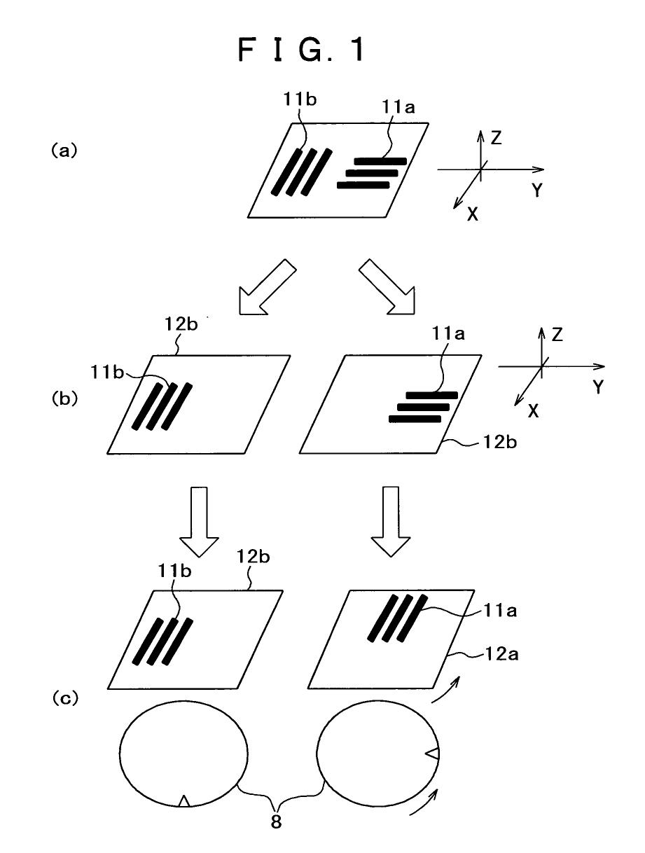

FIG. 1 shows a brief overview of an exposure method according to the present invention. In a lithography process that is one of processes for fabricating a semiconductor device, the exposure method explained here is applied to the projection of an LSI pattern necessary for configuring the semiconductor device on a wafer as an object to be exposed. In more detail, this exposure method is applied, while using a reflective mask for an EUV ray (wave-length=13.5 nm, for example) to project a mask pattern formed on the refection type mask on the wafer, thereby forms the LSI pattern on the wafer. The exposure light may be one of a charged particle beam, an X-ray, an Extreme Ultra Violet ray, an Ultra Violet ray, and a visible light, but the explanation in this text is done with the EUV ray as one of examples for the exposure light.

The mask pattern at this time includes pattern forming elements 11a of a V-line extending in a parallel direction relative to a direction of a projection vector of a skewed incident EUV ray as shown by (a) in FIG. 1, and pattern forming elements 11b of a H-line extending in a vertical direction relative to the projection vector. In order to project such mask pattern on a wafer, a reflective mask is prepared or formed by the procedures as described below.

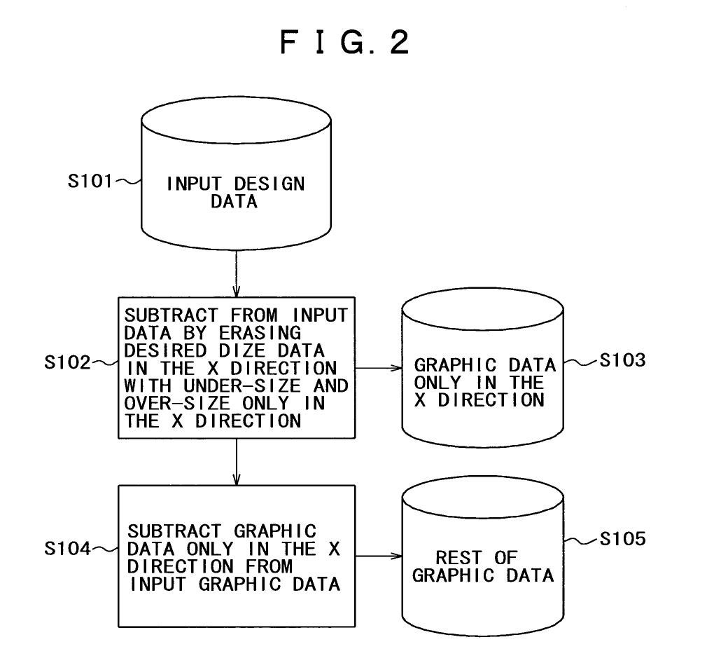

FIG. 2 is a flowchart designating a flow of procedures of a mask fabrication method according to the present invention. As shown in the figure, when forming the pattern of the reflective mask in the present embodiment, input design data (data for whole pattern) are acquired for the mask pattern corresponding to the LSI pattern to be formed on a wafer in a step S101. As the input design data, CAD (Computer Aided Design) data correspond to them, for example. Then, the input design data are divided into V-line data corresponding to the pattern forming elements 11a of the V-line, and H-line data corresponding to the pattern forming elements 11b of the H-line.

To be more specific, by erasing size data of over-size and under-size of only for an X direction in a step 102, the graphic data only for the X direction are extracted in a step S103. In this case, a coordinate space on the input design data is consistent with a coordinate space upon exposure. Accordingly, the graphic data extending in the X direction correspond to the H-line data, and the graphic data extending in the Y direction (that is, the operating direction of the exposure apparatus) correspond to the V-line data. After the graphic data only for the X direction are extracted, then the graphic data only for the X direction are subtracted from the input design data in a step S104, and the rest of the graphic data are extracted there-from in a step S105. These rest of the graphic data are to correspond to the graphic data extending in the Y direction, namely, the V-line data. As described above, in case of forming such reflective mask, it is necessary to divide the input design data for the mask pattern into the V-line data and the H-line data relative to respective direction with regard to the direction of the projection vector of the EUV ray.

Then, based on the divided V-line data and H-line data, a V-line mask 12a having a mask pattern consisting of the pattern forming elements 11a only for the V-line and an H-line mask 12b having a mask pattern consisting of the pattern forming elements 11b only for the H-line are respectively formed. Thus, the reflective masks 12a and 12b for respective direction are prepared.

In this case, the V-line mask 12a and the H-line mask 12b may be formed with a conventional method, so that the explanation thereof is omitted here. Further, regarding the division of the input design data into the divided V-line data and H-line data, it is not necessary to carry out by above mentioned procedures, and other graphic processing technology already known may be applied.

After the V-line mask 12a and the H-line mask 12b are prepared, the mask pattern is at first projected on the wafer 8 using one of the two masks. Namely, the EUV ray is irradiated on one of the V-line mask 12a and the H-line mask 12b, and forms on the wafer 8 either the mask pattern consisting of the pattern forming elements 11a only for the V-line or an H-line mask 12b having the mask pattern consisting of the pattern forming elements 11b only for the H-line by arriving the reflection light on the wafer 8.

After one of the pattern image is projected, the mask pattern of the other reflective mask 12a, or 12b is projected on the wafer 8. For example, if the process for the exposure and projection by using the V-line mask 12a, then the process for the exposure and projection by using the H-line mask 12b is carried out. In this case, the relative position of the H-line mask 12b which corresponds to the other reflective mask is rotated approximately by 90 degrees relative to the projection vector of the EUV ray. Further as shown in by (c) in FIG. 1, the relative position of the wafer 8 on which the pattern is projected is also rotated approximately by 90 degrees relative to the projection vector of the EUV ray.

Thereby, even if the irradiating object of the EUV ray is changed to the other reflective mask, namely to the H-line mask 12b, an angle of the pattern forming elements 11b of the H-line mask 12b and the projection vector of the EUV ray becomes equal to an angle of the pattern forming elements 11a of the V-line mask 12b and the projection vector of the EUV ray, wherein the exposure using the V-line mask 12b is finished in advance. Further, because the wafer 8 is also rotated by approximately 90 degrees, the projected image of the desired pattern is to be correctly formed on the wafer 8, even the H-line mask 12b is rotated by approximately 90 degrees when the mask is changed to the H-line mask 12b.

As explained above, according to the present embodiment, the V-line mask 12a and the H-line mask 12b are provided or formed by dividing a mask pattern regarding respective direction relative to the projection vector of the EUV ray. Then, the exposure and the projection by using respective reflective mask 12a and 12b is sequentially carried out. In this case, when the reflective masks 12a and 12b are changed from the one to the other, doubled exposures are to be carried out by rotating the other mask and the wafer 8. For the sake, even in the case where the EUV ray is coming askew to respective reflective mask 12a and 12b, the angle of the projection vector of the EUV ray and the respective pattern forming elements 11a and 11b of the respective reflective mask 12a and 12b is always the same. Accordingly, no adverse affect due to the angle of the projection vector and the pattern forming elements 11a and 11b principally occurs without depending on the correction of the mask pattern, so that it is as much possible to avoid occurrence of misalignment or distortion (distortion of pattern width) of the projected image. As a result, it is able to prevent the adverse affect of the direction of the mask pattern to the resolution of the projected image.

Particularly, if, as explained in the above mentioned embodiment, the exposure process is carried out twice using the V-line mask 12a and the H-line mask 12b in this order, and the extending directions of the pattern forming elements 11a and 11b are aligned in the direction of the projection vector of the EUV ray, it becomes very effective in case of improving the resolution of the projected image on the wafer 8 even when the EUV ray is incoming askew.

Further in case of forming an LSI pattern on the wafer 8, the pattern comprises of forming elements mainly extending in the directions of the V-line and the H-line, so that, as explained in the above mentioned embodiment, it is effective to expose twice using the V-line mask 11a and the H-line mask 11b from the perspective of the resolution, the efficiency of the process and the like, but the present invention is not limited to expose twice using the V-line mask 11a and the H-line mask 11b. For example, if sequential exposures and relative positional rotations are done with regard to respective direction by providing respective reflective mask with regard to respective direction regarding the projection vector of the EUV ray, the exposure process may be carried out three times or more. That is, the above mentioned is one of embodiments of the present invention, and the scope of the present invention is not limited to this. Further the exposure light of the present invention is not limited to the EUV ray, and the exposure light may be one of a charged particle beam, an X-ray, an Extreme Ultra Violet ray, an Ultra Violet ray, and a visible light.

What is claimed is:

1. An exposure method for projecting a desired pattern on an object to be exposed utilizing a reflective mask for an exposure light, comprising the steps of:
providing respective reflective mask each having a mask pattern consisting of only pattern forming elements of the same direction with regard to the respective longitudinal direction by dividing pattern forming elements of the mask pattern corresponding to said desired pattern relative to a projection vector of the exposure light;
sequentially carrying out projection of said mask pattern on said object to be exposed by irradiating said exposure light and its reflection light with regard to respective reflective mask in the respective direction; and
rotating, when one reflective mask is changed to the other reflective mask, said other reflective mask and said object to be exposed so that an angle of the pattern forming elements of said the other reflective mask and the projection vector becomes equal to an angle of the pattern forming elements of said one reflective mask and the projection vector.

2. The exposure method as cited in claim 1, wherein
said reflective mask of the respective direction includes a V-line mask having a pattern only including the pattern forming elements perpendicular to said projection vector, and an H-line mask having a pattern only including the pattern forming elements horizontal to said projection vector.

3. The exposure method as cited in claim 1, wherein
said exposure light is one of a charged particle beam, an X-ray, an Extreme Ultra Violet ray, an Ultra Violet ray, and a visible light.

4. The exposure method as cited in claim 3, wherein
said charged particle beam is one of an electron beam and an ion beam.

5. The exposure method as cited in claim 2, wherein
a perpendicular direction of the mask pattern including the pattern forming elements formed on said V-line mask relative to said projection vector corresponds to an scanning direction of an exposure apparatus.

6. The exposure method as cited in claim 1, wherein
a rotation angle of said rotation is approximately 90 degrees with regard to said object to be exposed.

7. The exposure method as cited in claim 1, wherein
said projection process is sequentially carried out twice or more than twice.

8. A mask fabrication method for projecting a desired pattern on an object to be exposed utilizing a reflective mask for an exposure light, comprising the steps of:
dividing pattern forming elements of a mask pattern corresponding to said desired pattern with regard to respective direction relative to a projection vector of the exposure light;
forming respective reflective mask each having a mask pattern consisting of only pattern forming elements of the same direction with regard to the respective direction; and
forming respective reflective mask of respective direction so that when the reflective mask and said object to be exposed are rotated relative to said projection vector, an angle of the pattern forming elements of respective reflective mask and the projection vector is always the same.

9. The mask fabrication method as cited in claim 8, wherein
said reflective mask of the respective direction includes a V-line mask having a pattern only including the pattern forming elements perpendicular to said projection vector, and an H-line mask having a pattern only including the pattern forming elements horizontal to said projection vector.

10. The mask fabrication method as cited in claim 8, wherein
said exposure light is one of a charged particle beam, an X-ray, an Extreme Ultra Violet ray, an Ultra Violet ray, and a visible light.

11. The mask fabrication method as cited in claim 10, wherein
said charged particle beam is one of an electron beam and an ion beam.

12. The mask fabrication method as cited in claim 9, wherein
a perpendicular direction of the mask pattern including the pattern forming elements formed on said V-line mask relative to said projection vector corresponds to an scanning direction of an exposure apparatus.

13. The mask fabrication method as cited in claim 9, wherein
said dividing process for the mask pattern corresponding to the desired pattern includes:
erasing desired size data in the X direction with the under size or over-size only in the X direction from an input design data;
extracting H-line data which is graphic data of only X direction; and
extracting the rest of graphic data by subtracting the graphic data of only X direction from said input design data as V-line data so that said rest of the graphic data corresponds to the V-line data extending in Y direction.

14. The mask fabrication method as cited in claim 8, wherein
a rotation angle of said rotation is approximately 90 degrees with regard to said object to be exposed.

15. A fabrication method of a semiconductor device including a lithography process for projecting a desired pattern on an object to be exposed using a reflective mask for an exposure light, comprising the steps of:
providing respective reflective mask each having a mask pattern consisting of only pattern forming elements of the same direction with regard to the respective direction by dividing pattern forming elements of the mask pattern corresponding to said desired pattern relative to a projection vector of the exposure light;
sequentially carrying out projection of said mask pattern on said object to be exposed by irradiating said exposure light and its reflection light with regard to respective reflective mask in the respective direction; and
rotating, when one reflective mask is changed to the other reflective mask, said other reflective mask and said object to be exposed so that an angle of the pattern forming elements of said the other reflective mask and the projection vector becomes equal to an angle of the pattern forming elements of said one reflective mask and the projection vector.

16. The fabrication method of a semiconductor device as cited in claim 15, wherein
said reflective mask of the respective direction includes a V-line mask having a pattern only including the pattern forming elements perpendicular to said projection vector, and an H-line mask having a pattern only including the pattern forming elements horizontal to said projection vector.

17. The fabrication method of a semiconductor device as cited in claim 15, wherein
said exposure light is one of a charged particle beam, an X-ray, an Extreme Ultra Violet ray, an Ultra Violet ray, and a visible light.

18. The fabrication method of a semiconductor device as cited in claim 17, wherein
said charged particle beam is one of an electron beam and an ion beam.

19. The fabrication method of a semiconductor device as cited in claim 16, wherein
a perpendicular direction of the mask pattern including the pattern forming elements formed on said V-line mask relative to said projection vector corresponds to an operating direction of an exposure apparatus.

20. The fabrication method of a semiconductor device as cited in claim 15, wherein
a rotation angle of said rotation is approximately 90 degrees with regard to said object to be exposed.
